(19) United States
(12) Patent Application Publication
(10) Pub. No.: US 2013/0153911 A1
(43) Pub. Date: Jun. 20, 2013

(54) ARRAY SUBSTRATE, MANUFACTURING METHOD THEREOF AND DISPLAY DEVICE

(71) Applicants: Feng Zhang, Beijing (CN); Tianming Dai, Beijing (CN); Qi Yao, Beijing (CN)

(72) Inventors: Feng Zhang, Beijing (CN); Tianming Dai, Beijing (CN); Qi Yao, Beijing (CN)

(73) Assignee: BOE TECHNOLOGY GROUP CO., LTD., Beijing (CN)

(21) Appl. No.: 13/806,190

(22) PCT Filed: Nov. 2, 2012
(86) PCT No.: PCT/CN12/83985

§ 371 Date: Dec. 21, 2012

(30) Foreign Application Priority Data
Dec. 15, 2011 (CN) 201110421568.7

(51) Int. Cl. H01L 29/66

(52) U.S. Cl. 257/59; 438/34; 257/72

(57) ABSTRACT

Embodiments of the present invention provide a method of manufacturing an array substrate, comprising: a step of forming a pixel electrode and a step of forming a common electrode, wherein at least one of the pixel electrode and the common electrode is formed of graphene. The embodiments of the present invention also provide an array substrate manufactured by the above method and a display device comprising the array substrate.

### FIELD OF THE INVENTION

Embodiments of the present invention relate to an array substrate, a manufacturing method thereof and a display device.

### BACKGROUND

Thin film transistor liquid crystal displays (TFT-LCDs) have characteristics such as small size, low power consumption, being free of radiation and etc., and have dominated the current flat-panel display market.

Currently, a pixel electrode and a common electrode in the TFT-LCDs mostly employ indium tin oxide (ITO). However, the ITO has a high price and is easy to cause ion diffusion in the presence of acid and alkali. The diffused ion will cause harm to the environment and the human health, and ion diffused into a device will degrade the performance of the device. In addition, the ITO material is relatively brittle and prone to be damaged in the event of deformation; therefore it is difficult to be applied to the field of flexible display.

### SUMMARY

One embodiment according to the present invention provides a method of manufacturing an array substrate, comprising: a step of forming a pixel electrode and a step of forming a common electrode, wherein at least one of the pixel electrode and the common electrode is formed of graphene.

Another embodiment according to the present invention provides an array substrate, comprising a pixel electrode and a common electrode, wherein at least one of the pixel electrode and the common electrode is made of graphene.

Still another embodiment according to the present invention provides a display device, comprising a pixel electrode and a common electrode, wherein at least one of the pixel electrode and the common electrode is made of graphene.

### BRIEF DESCRIPTION OF THE DRAWINGS

To illustrate technical solutions in embodiments of the present invention more clearly, accompanied drawings of the embodiments will be briefly introduced below. Obviously, the accompanied drawings described below merely relate to some embodiments of the present invention, and are not limitation on the present invention.

FIG. 1 is a schematic plan view of an array substrate after a first patterning process according to a first embodiment of the present invention;

FIG. 2 is a schematic sectional view of the array substrate after the first patterning process according to the first embodiment of the present invention;

FIG. 3 is a schematic plan view of the array substrate after a second patterning process according to the first embodiment of the present invention;

FIG. 4 is a schematic sectional view of the array substrate after the second patterning process according to the first embodiment of the present invention;

FIG. 5 is a schematic plan view of the array substrate after a third patterning process according to the first embodiment of the present invention;

FIG. 6 is a schematic sectional view of the array substrate after the third patterning process according to the first embodiment of the present invention;

FIG. 7 is a schematic sectional view of the array substrate after a fourth patterning process according to the first embodiment of the present invention;

FIG. 8 is a schematic plan view of the array substrate after a fifth patterning process according to the first embodiment of the present invention;

FIG. 9 is a schematic sectional view of the array substrate after the fifth patterning process according to the first embodiment of the present invention;

FIG. 10 is a schematic plan view of an array substrate after a first patterning process according to a second embodiment of the present invention;

FIG. 11 is a schematic sectional view of the array substrate after the first patterning process according to the second embodiment of the present invention;

FIG. 12 is a schematic plan view of the array substrate after a second patterning process according to the second embodiment of the present invention;

FIG. 13 is a schematic sectional view of the array substrate after the second patterning process according to the second embodiment of the present invention;

FIG. 14 is a schematic plan view of the array substrate after a third patterning process according to the second embodiment of the present invention;

FIG. 15 is a schematic sectional view of the array substrate after the third patterning process according to the second embodiment of the present invention;

FIG. 16 is a schematic sectional view of the array substrate after a fourth patterning process according to the second embodiment of the present invention;

FIG. 17 is a schematic plan view of the array substrate after the fourth patterning process according to the second embodiment of the present invention.

### DETAILED DESCRIPTION

In order to make objects, technical details and advantages of the embodiments of the invention apparent, hereinafter, technical solutions in embodiments of the present invention will be clearly and fully described in combination with the accompanied drawings in the embodiments of the present invention. Apparently, the embodiments to be described are merely a part but not all of embodiments of the present invention. Every other embodiment as would be obvious to those ordinarily skilled in the art on the basis of described embodiments in the present invention without creative work, comes within the protection scope of the present invention.

Embodiments of the present invention aims at the problems in the prior art of high cost of pixel electrode and common electrode employing ITO and device performance degradation due to the ITO being prone to ion diffusion. The embodiments of the present invention provide an array substrate, a manufacturing method thereof, and a display device, which can reduce the manufacturing cost of the array substrate, and improve the performance of the array substrate.

The embodiments of the invention provide a method of manufacturing an array substrate, wherein the manufacturing method employs graphene to fabricate a pixel electrode and/or a common electrode of the array substrate. In addition, the manufacturing method can form a source electrode, a drain electrode and the pixel electrode simultaneously by one patterning process.

The embodiments of the present invention also provide an array substrate manufactured by the above method, and the array substrate comprises a pixel electrode and a common electrode, wherein at least one of the pixel electrode and the common electrode is made of graphene. In addition, the array substrate further comprises a source electrode and a drain electrode, wherein the source electrode, the drain electrode and the pixel electrode are in the same layer, and the source electrode, the drain electrode and the pixel electrode are each made of graphene.

The embodiments of the present invention also provide a display device, comprising the above-mentioned array substrate.

Graphene is a new carbonaceous material with monolayer of carbon atoms closely packed into a two-dimensional honeycomb structure. The intrinsic electron mobility of graphene at room temperature is up to 200000 cm²/Vs, which is 140 times larger than that of Si (1400 cm²/Vs), 20 times larger than that of GaAs (8500 cm²/Vs), and 100 times larger than that of GaN (2000 cm²/Vs). At room temperature, graphene has a resistance value which is only ⅔ of that of copper (Cu). Graphene can also withstand a current density of 100 million to 200 million A/cm², which is about 100 times larger than the Cu tolerance amount. Meanwhile, graphene also has excellent light transmittance, electrical conductivity, thermal conductivity, and chemical stability. Accordingly, the present invention employs graphene to fabricate the source electrode, the drain electrode, the pixel electrode and/or the common electrode of the array substrate, which can reduce the manufacturing cost of the array substrate, and improve the performance of the array substrate. Further, the present invention forms the source electrode, the drain electrode and the pixel electrode simultaneously through one patterning process, which can reduce the number of process steps, and thus improve the productivity.

The array substrate and the manufacturing method thereof according to the present invention will be further described in conjunction with specific embodiments:

### First Embodiment

A liquid crystal display of Advanced Super Dimension Switch (ADSDS) technology is described as an example in the present embodiment. A multi-dimensional electric field is formed with both an electric field produced at edges of slit electrodes in the same plane and an electric field produced between a slit electrode layer and a plate-like electrode layer in the ADSDS technology, so that liquid crystal molecules at all orientations, which are located directly above the electrodes and between the slit electrodes in a liquid crystal cell, can be rotated, thereby enhancing the work efficiency of liquid crystals and increasing the light transmittance. The Advanced Super Dimensional Switch technology can improve the picture quality of TFT-LCDs and has advantages of high resolution, high transmittance, lower power consumption, wide viewing angle, high aperture ratio, low chromatic aberration, being free of push Mura, etc. However, it should be noted that the embodiment according to the invention is not limited to the array substrate of ADSDS technology, and it can also be applied to manufacturing an array substrate of other mode liquid crystal displays or an array substrate of organic light emitting display.

FIGS. 1-9 are flow diagrams of a method of manufacturing an array substrate according to the present embodiment. As shown in FIGS. 1-9, the manufacturing method of the array substrate according to the present embodiment comprises the following steps:

Step 1: a first patterning process, forming a gate line made of a metal layer on a transparent substrate;

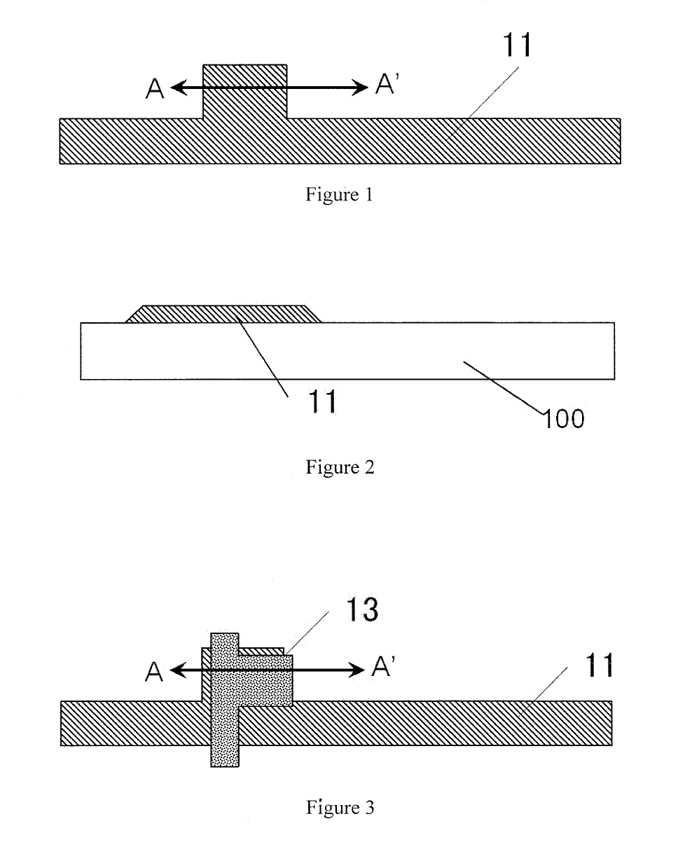

The metal layer is deposited on the transparent substrate 100, as shown in FIGS. 1 and 2, and the gate line 11 is formed by a patterning process. The patterning process may comprise, for example, coating, exposure, developing, etching and lifting off steps. FIG. 1 is a schematic plan view, and FIG. 2 is a schematic sectional view taken along A-A′ of the structure shown in FIG. 1. The metal layer can employ any one selected from a group consisting of Nd, Cr, W, Ti, Ta, Mo, Al and Cu or an alloy of at least two of these metals;

Step 2: a second patterning process, forming a gate insulating layer and an active layer made of a semiconductor layer on the transparent substrate after the first patterning process;

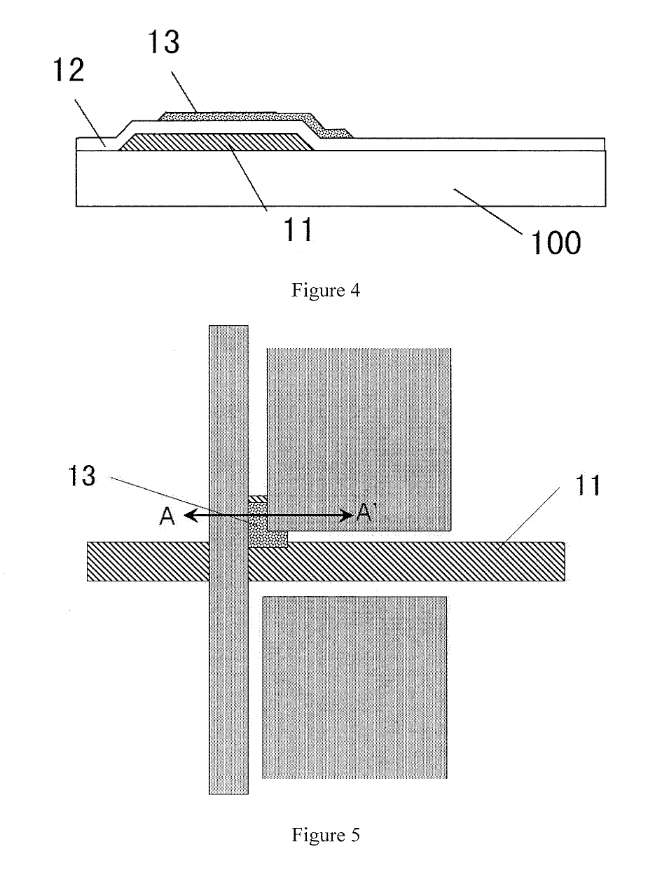

As shown in FIGS. 3 and 4, the gate insulating layer 12 and the semiconductor layer are sequentially deposited on the transparent substrate after the Step 1, and the active layer 13 is formed by a patterning process. FIG. 3 is a schematic plan view, and FIG. 4 is a schematic sectional view taken along A-A′ of the structure shown in FIG. 3. The gate insulating layer can employ SiNx, SiO₂, resin, or the like, and the semiconductor layer can employ amorphous silicon (a-Si), n⁺ amorphous silicon (n⁺ a-Si), low-temperature polysilicon, IGZO, or the like;

Step 3: a third patterning process, forming a source electrode, a drain electrode and a pixel electrode made of a first graphene layer on the transparent substrate after the second patterning process;

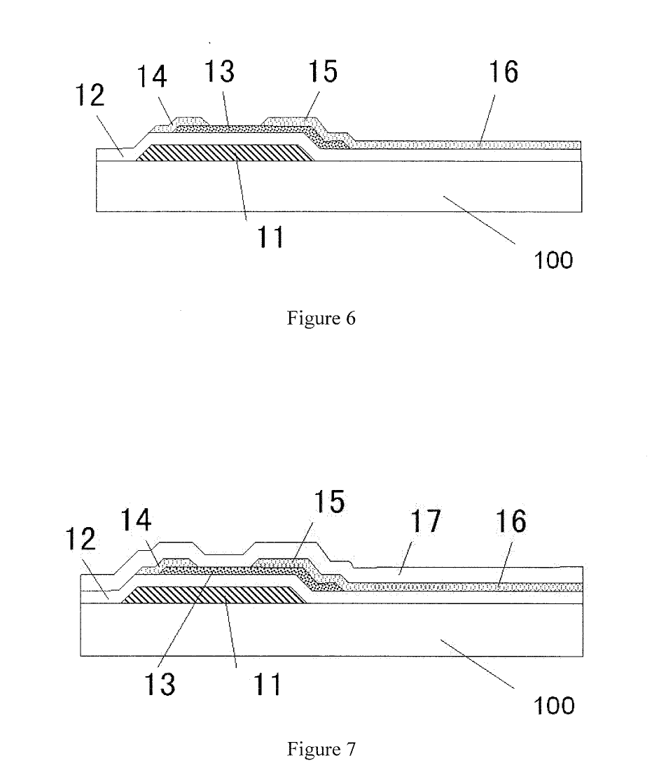

A layer of graphene film, i.e., the first the graphene layer, is deposited on the transparent substrate after the Step 2. As shown in FIG. 5 and FIG. 6, the source electrode 14, the drain electrode 15 and the pixel electrode 16 are formed by a patterning process.

FIG. 5 is a schematic plan view, and FIG. 6 is a schematic sectional view taken along A-A′ of the structure shown in FIG. 5. In the present embodiment, the source electrode, the drain electrode, and the pixel electrode material are each of graphene films;

In the present embodiment, a data the line and the source electrode on the array substrate 14 may be integrally fabricated; therefore, the data line can also be made of graphene. Of course, in the actual production process, the data line and the source electrode may be fabricated by using different materials as required.

Step 4: a fourth patterning process, Ruining a passivation layer on the transparent substrate after the third patterning process, the passivation layer having a via hole for a peripheral circuit;

A passivation material layer is deposited on the transparent substrate after the Step 3, as shown in FIG. 7, and the passivation layer 17 is formed by a patterning process. The passivation layer 17 has a via hole for a peripheral circuit. The passivation layer may employ SiNx, SiO₂, resin, or the like;

Step 5: a fifth patterning process, forming a common electrode made of a second graphene layer on the transparent substrate after the fourth patterning process.

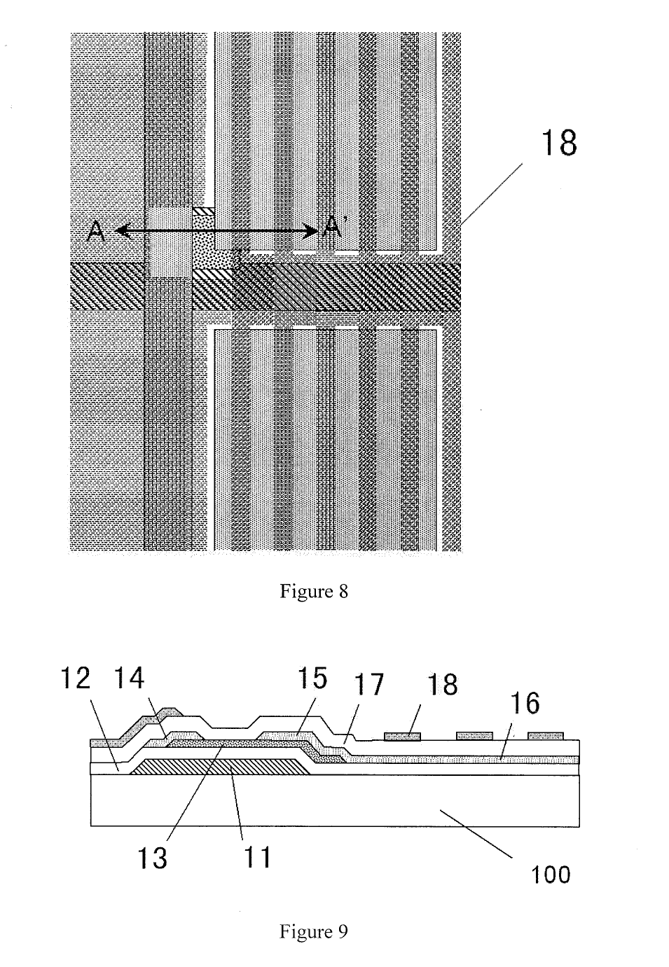

A layer of graphene film, i.e. the second graphene layer, is deposited on the transparent substrate after the Step 4, as shown in FIGS. 8 and 9, and the common electrode layer 18 is formed by a patterning process. FIG. 8 is a schematic plan view, FIG. 9 is a schematic sectional view taken along A-A′ of the structure shown in FIG. 8.

Finally, after the above steps 1-5, the array substrate as shown in FIG. 9 is Ruined.

In the array substrate, the source electrode, the drain electrode and the pixel electrode are formed through patterning the same material layer; therefore, they are provided in the same layer.

In the present embodiment, it is preferable that the pixel electrode layer and the common electrode layer are each fabricated by using graphene; but implements of the technical solutions provided by the present invention are not limited thereto. For example, one layer of the pixel electrode layer and the common electrode layer can be fabricated by using graphene, while the other layer is fabricated by using a conventional ITO or indium zinc oxide (IZO).

In this embodiment, the source electrode, the drain electrode, the pixel electrode and the common electrode of the array substrate are fabricated by graphene, which can reduce the manufacturing cost of the array substrate, and improve the performance of the array substrate. Meanwhile, the source electrode, the drain electrode and the pixel electrode are simultaneously formed through one patterning process in the present embodiment, which can reduces the number of process steps and thus enhance the productivity.

### Second Example

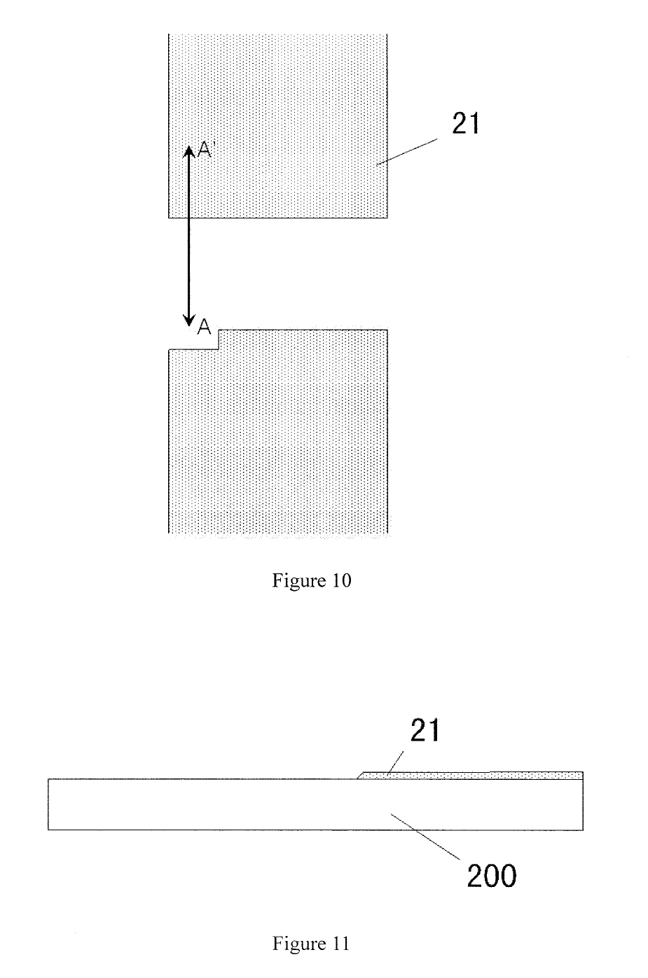

FIGS. 10-17 are flow diagrams showing a manufacturing method of an array substrate according to the embodiment, with an ADSDS type array substrate as an example. As shown in FIGS. 10-17, the method of manufacturing of the array substrate according to the present embodiment comprises the following steps:

Step 1: a first patterning process, forming a common electrode made of a first graphene layer on a transparent substrate;

A graphene thin film, i.e., the first graphene layer, is deposited on the transparent substrate 200, as shown in FIGS. 10 and 11, and the common electrode 21 is formed by a patterning process. FIG. 10 is a schematic plan view, FIG. 11 is a schematic sectional view taken along A-A′ of the structure shown in FIG. 10. The patterning process may comprise, for example, coating, exposure, developing, etching, lifting off, and other steps;

Step 2: a second patterning process, forming a common electrode line and a gate line made of a metal layer on the transparent substrate after the first patterning process;

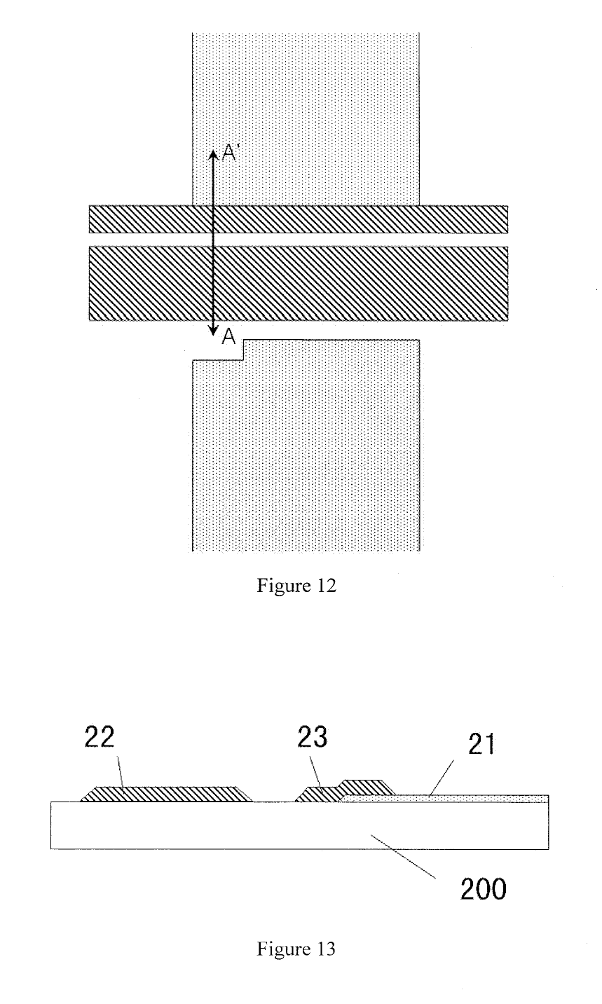

The metal layer is deposited on the transparent substrate after the step 1, as shown in FIGS. 12 and 13, and the gate line 22 and the common electrode line 23 are formed by a patterning process. FIG. 12 is a schematic plan view, and FIG. 13 is a schematic sectional view taken along A-A′ of the structure shown in FIG. 12. The metal layer may be any one selected from a group consisting of Nd, Cr, W, Ti, Ta, Mo, Al and Cu, or alloys of these metals;

Step 3: a third patterning process, forming a gate insulating layer, an active layer made of a semiconductor layer, and an etch stop layer made of an insulating layer on the transparent substrate after the second patterning process;

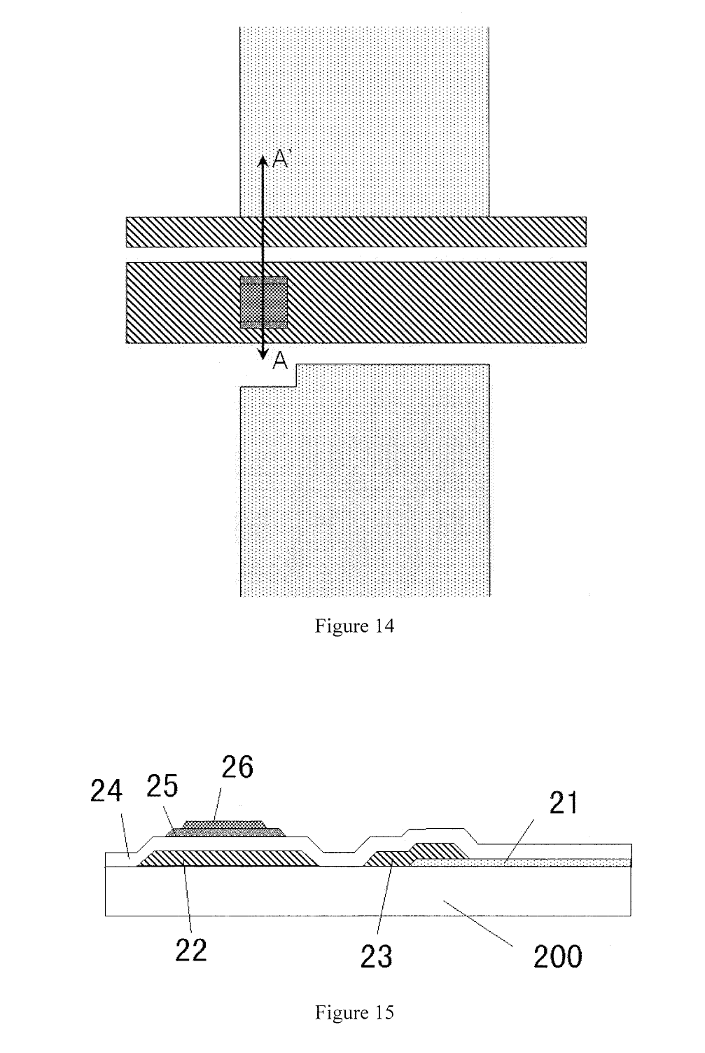

The gate insulating layer 24, the semiconductor layer and a passivation layer are successively deposited on the transparent substrate after the step 2, as shown in FIGS. 14 and 15, the active layer 25 and the etching stopper layer 26 are sequentially formed through a patterning process over the gate lines 22. FIG. 14 is a schematic plan view, and

FIG. 15 is a schematic sectional view taken along A-A′ of the structure shown in FIG. 14. The gate insulating layer and the passivation layer may employ SiNx, SiO₂, resin, or the like. The etch stop layer 26 can have a function of protecting the channel, so as to prevent the channel from being damaged and polluted in the subsequent etching and other processes. The semiconductor layer may employ amorphous silicon (a-Si) thin film, n⁺ amorphous silicon (n⁺ a-Si) thin film, low-temperature polysilicon, IGZO, or the like;

Step 4: a fourth patterning process, forming a source electrode, a drain electrode and a pixel electrode made of a second graphene layer on the transparent substrate after the third patterning process.

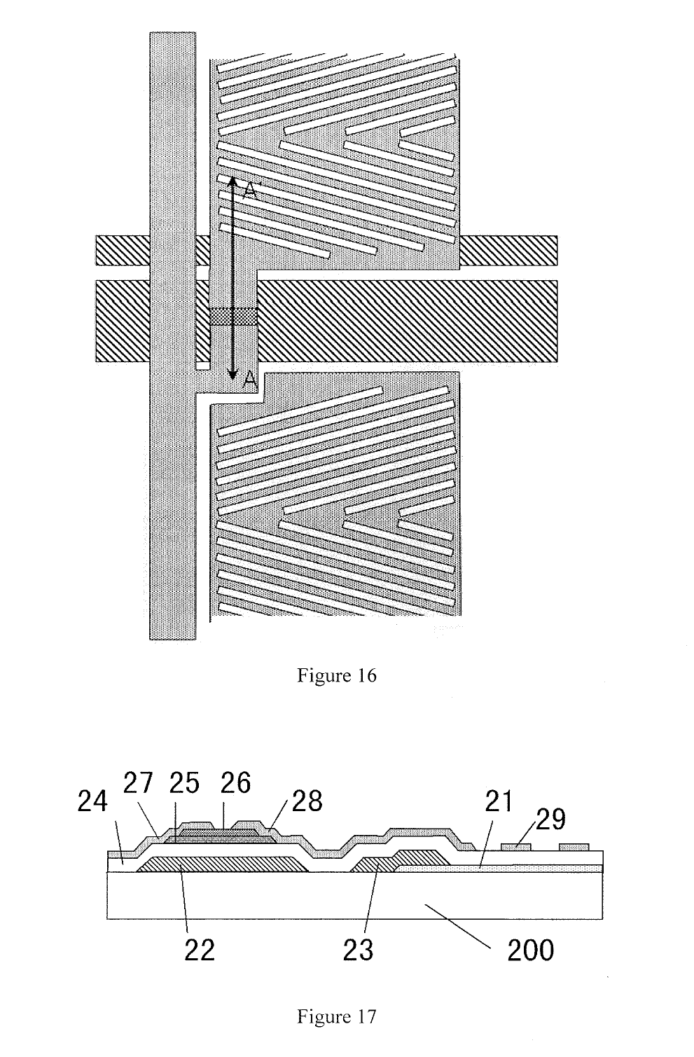

A layer of graphene film, i.e. the second graphene layer, is deposited on the transparent substrate after the Step 3, as shown in FIGS. 16 and 17, and the source electrode 27, the drain electrode 28 and the pixel electrode 29 are formed through a patterning process. FIG. 16 is a schematic plan view, and FIG. 17 is a schematic sectional view taken along A-A′ of the structure shown in FIG. 16. In the present embodiment, the source electrode, the drain electrode, the pixel electrode materials are each of graphene films.

In the present embodiment, a data line and the source electrode 27 on the array substrate may be integrally fabricated; therefore, the data line may also be made of graphene. Of course, in the actual production process, the data line and the source electrode may be fabricated by using different materials as required.

Finally, after the above steps 1-4, the array substrate shown in FIG. 17 is formed.

In the array substrate, the source electrode, the drain electrode and the pixel electrode are formed by patterning the same material layer pattern; therefore, they are provided in the same layer.

In the present embodiment, it is preferable that the pixel electrode layer and the common electrode layer both are fabricated by using grapheme. However, the implements of the technical solutions provided by the present invention are not limited thereto. For example, one layer of the pixel electrode layer and the common electrode layer can be fabricated by using graphene, while the other layer can be fabricated by using a conventional ITO or indium zinc oxide (IZO).

In this embodiment, graphene is used to fabricate the source electrode, the drain electrode, the pixel electrode and the common electrode of the array substrate, which can reduce the manufacturing cost of the array substrate, and improve the performance of the array substrate. Meanwhile, the present embodiment forms the source electrode, the drain electrode and the pixel electrode of the array substrate simultaneously through one patterning process, thereby reducing the number of process steps, and enhancing the productivity.

In addition, although the above description is made by taking an ADSDS type array substrate as an example, the array substrate and the manufacturing method thereof according to the present invention can be applied to other modes of array substrate, for example, in-plane switch (IPS) mode array substrate. Further, the array substrate according to the embodiment of the present invention does not necessarily comprise the common electrode. For example, the array substrate according to the embodiment of the invention may be an array substrate for a liquid crystal display of vertical electric field mode; in this case, the common electrodes may not be formed on the array substrate.

An embodiment of the present invention further provides a display device comprising a pixel electrode and a common electrode, wherein at least one of the pixel electrode and the common electrode is made of graphene. For example, the display device may comprise any of the above-described array substrates, and the pixel electrode and the common electrode each are formed on the array substrate; alternatively, the array substrate is only formed with the pixel electrode and the common electrode is formed on another substrate (e.g., a counter substrate) of the display device.

The array substrates according to the above embodiments each can be applied to the display device according to the embodiments of the present invention; therefore, the display device according to the embodiments of the present invention also have the above-described structural features and the corresponding technical effects, which are not repeated here.

For example, the display device according to the present invention can be a liquid crystal display device, such as a liquid crystal panel, a liquid crystal TV, a mobile phone, a liquid crystal display, etc., comprising a color filter substrate, and the array substrate in above-described embodiment. In addition to the liquid crystal display device, the display device can also be other types of display devices, such as an electronic reader, etc., and it does not comprise the color filter substrate, but comprises the array substrate in the above-described embodiment. Further, the display device according to the present invention can also be an organic light emitting display.

In each method embodiments according to the invention, the serial number of each step cannot be used to define the sequence of the steps. For those skilled in the art, variation on the sequence of the steps without creative effort should also be comprised within the protection scope of the present invention.

Based on the above description, the embodiments in accordance with the present invention can provide at least the following methods and structures:

(1) A method of manufacturing an array substrate, comprising: a step of forming a pixel electrode and a step of forming a common electrode, wherein at least one of the pixel electrode and the common electrode is formed of graphene.

(2) The method of manufacturing the array substrate according to (1), wherein, in the step of forming the pixel electrode, a source electrode and a drain electrode are simultaneously formed with the pixel electrode in the same patterning process, and the source electrode, the drain electrode and the pixel electrode are each made of graphene.

(3) The method of manufacturing the array substrate according to (1) or (2), wherein the step of forming the pixel electrode is performed before the step of forming the common electrode, and wherein, before the step of forming the pixel electrode, the method further comprises: forming a gate line made of a metal layer on the substrate; fainting a gate insulating layer and an active layer made of a semiconductor layer on the substrate formed with gate line.

(4) The method of manufacturing the array substrate according to (3), wherein, after the step of forming the pixel electrode and before the step of forming the common electrode, the method further comprises: forming a passivation layer on the substrate formed with the pixel electrode, the passivation layer having a via hole for a peripheral circuit therein.

(5) The method of manufacturing the array substrate according to (1) or (2), wherein the step of forming the common electrode is performed before the step of forming the pixel electrode, and wherein, between the step of forming the common electrode and the step of forming the pixel electrode, the method further comprises: forming a common electrode line and a gate line made of a metal layer on the substrate formed with the common electrode; and forming a gate insulating layer, an active layer made of a semiconductor layer and an etch stop layer made of an insulating layer on the substrate formed with the gate line and the common electrode line.

(6) The method of manufacturing the array substrate according to any of (1)-(5), wherein the step of forming the pixel electrode comprises: forming a graphene layer; and patterning the graphene layer to form the source electrode, the drain electrode and the pixel electrode.

(7) The method of manufacturing the array substrate according to any of (1)-(6), wherein the step of forming the common electrode comprises: forming a graphene layer; and patterning the graphene layer to form the common electrode.

(8) The method of manufacturing the array substrate according to (3) or (5), wherein a material of the metal layer is at least one selected from a group consisting of Nd, Cr, W, Ti, Ta, Mo, Al, and Cu.

(9) The method of manufacturing the array substrate according to (3) or (5), wherein a material of the gate insulating layer is SiNx. SiO₂, or resin.

(10) The method of manufacturing the array substrate according to (4) or (5), wherein a material of the passivation layer is SiNx, SiO₂, or resin.

(11) The method of manufacturing the array substrate according to (3) or (5), wherein a material of the semiconductor layer is amorphous silicon, low-temperature polysilicon or indium gallium zinc oxide.

(12) An array substrate, comprising a pixel electrode and a common electrode, wherein at least one of the pixel electrode and the common electrode is made of graphene.

(13) The array substrate according to (12), further comprising a source electrode and a drain electrode, wherein the source electrode, the drain electrode and the pixel electrode are disposed in the same layer, and the source electrode, the drain electrode and the pixel electrode are each made of graphene.

(14) The array substrate according to (13), wherein the source electrode, the drain electrode and the pixel electrode are formed simultaneously in the same patterning process.

(15) A display device, comprising a pixel electrode and a common electrode, wherein at least one of the pixel electrode and the common electrode is made of graphene.

(16) The display device according to (15), wherein the display device comprises an array substrate, and the pixel electrode and the common electrode are each formed on the array substrate.

(17) The display device according to (15) or (16), further comprising a source electrode and a drain electrode, wherein the source electrode, the drain electrode and the pixel electrode are disposed in the same layer, and the source electrode, the drain electrode and the pixel electrodes are each made of graphene.

(18) The display device according to (17), wherein the source electrode, the drain electrode and the pixel electrode are simultaneously formed in the same patterning process.

What is claimed is:

1. A method of manufacturing an array substrate, comprising: a step of forming a pixel electrode and a step of forming a common electrode, wherein at least one of the pixel electrode and the common electrode is formed of graphene.

2. The method of manufacturing the array substrate according to claim 1, wherein, in the step of forming the pixel electrode, a source electrode and a drain electrode are simultaneously formed with the pixel electrode in the same patterning process, and the source electrode, the drain electrode and the pixel electrode are each made of graphene.

3. The method of manufacturing the array substrate according to claim 2, wherein the step of forming the pixel electrode is performed before the step of forming the common electrode, and
wherein, before the step of forming the pixel electrode, the method further comprises:
forming a gate line made of a metal layer on the substrate;
forming a gate insulating layer and an active layer made of a semiconductor layer on the substrate formed with gate line.

4. The method of manufacturing the array substrate according to claim 3, wherein, after the step of forming the pixel electrode and before the step of forming the common electrode, the method further comprises:
forming a passivation layer on the substrate formed with the pixel electrode, the passivation layer having a via hole for a peripheral circuit therein.

5. The method of manufacturing the array substrate according to claim 2, wherein the step of forming the common electrode is performed before the step of forming the pixel electrode, and
wherein, between the step of forming the common electrode and the step of forming the pixel electrode, the method further comprises:
forming a common electrode line and a gate line made of a metal layer on the substrate formed with the common electrode; and
forming a gate insulating layer, an active layer made of a semiconductor layer and an etch stop layer made of an insulating layer on the substrate formed with the gate line and the common electrode line.

6. The method of manufacturing the array substrate according to claim 2, wherein the step of forming the pixel electrode comprises:
forming a graphene layer; and
patterning the graphene layer to form the source electrode, the drain electrode and the pixel electrode.

7. The method of manufacturing the array substrate according to claim 2, wherein the step of forming the common electrode comprises:
forming a graphene layer; and
patterning the graphene layer to form the common electrode.

8. The method of manufacturing the array substrate according to claim 3, wherein a material of the metal layer is at least one selected from a group consisting of Nd, Cr, W, Ti, Ta, Mo, Al, and Cu.

9. The method of manufacturing the array substrate according to claim 3, wherein a material of the gate insulating layer is SiNx, SiO₂, or resin.

10. The method of manufacturing the array substrate according to claim 4, wherein a material of the passivation layer is SiNx, SiO₂, or resin.

11. The method of manufacturing the array substrate according to claim 3, wherein a material of the semiconductor layer is amorphous silicon, low-temperature polysilicon or indium gallium zinc oxide.

12. An array substrate, comprising a pixel electrode and a common electrode, wherein at least one of the pixel electrode and the common electrode is made of graphene.

13. The array substrate according to claim 12, further comprising a source electrode and a drain electrode, wherein the source electrode, the drain electrode and the pixel electrode are disposed in the same layer, and the source electrode, the drain electrode and the pixel electrode are each made of graphene.

14. The array substrate according to claim 13, wherein the source electrode, the drain electrode and the pixel electrode are formed simultaneously in the same patterning process.

15. A display device, comprising a pixel electrode and a common electrode, wherein at least one of the pixel electrode and the common electrode is made of graphene.

16. The display device according to claim 15, wherein the display device comprises an array substrate, and the pixel electrode and the common electrode are each formed on the array substrate.

17. The display device according to claim 15, further comprising a source electrode and a drain electrode, wherein the source electrode, the drain electrode and the pixel electrode are disposed in the same layer, and the source electrode, the drain electrode and the pixel electrodes are each made of graphene.

18. The display device according to claim 17, wherein the source electrode, the drain electrode and the pixel electrode are simultaneously formed in the same patterning process.
